(19) United States
(12) Patent Application Publication
(10) Pub. No.: US 2011/0017274 A1
(43) Pub. Date: Jan. 27, 2011

(54) Large Tracking-Type Fresnel Lens Point-Focusing Solar System

(76) Inventors: Zhong Huang, Sichuan (CN); Xiangyang Li, Sichuan (CN)

Correspondence Address: Anova Law Group, PLLC, 8230 Boone Blvd, Suite 347, Vienna, VA, 22182, US

(21) Appl. No.: 12/933,667

(22) PCT Filed: Jan. 5, 2010
(86) PCT No.: PCT/CN10/70017

§ 371 Date: Sep. 20, 2010

(30) Foreign Application Priority Data
Jan. 6, 2009 (CN) 200910058051.9

(51) Int. Cl. H01L 31/052; F24J 2/52; F24J 2/08; F24J 2/48

(52) U.S. Cl. 136/246; 126/600; 126/698; 126/676

(57) ABSTRACT

The invention provides a large trailing-type Fresnel lens point-focusing solar power system, it comprises a box body, a point-focusing glass matrix Fresnel lens, a reflecting low-radiation glass, a photovoltaic component, a high-temperature heat accumulator and a tracker. The point-focusing glass Fresnel lens, the reflecting low-radiation glass and the photovoltaic component are arranged in proper sequence from up to down, and respectively arranged on the upper part, the middle part and the low part of the box body. The high-temperature heat accumulator is positioned on the point-focusing glass matrix Fresnel lens. The high-temperature heat accumulator is fixed and arranged on a transverse bracket connected with the box body. The box body is arranged on the tracker, and traces the sun by the drive of the tracker. The invention relates to a trailing and spotlighting technique and a sunlight selective transmission technique, it is a high-efficiency clean photoelectric and photothermic utilization method.

### THE TECHNICAL FIELD

The invention is related to a large trailing-type Fresnel lens point-focusing solar power system, belonging to the field of solar power photothermic and photoelectric application.

### BACKGROUND

Solar power is an important part of new energy resources and renewable energy resources. There is great market prospect for the exploitation of the solar energy resources. It not only has sound social and environmental effects but also has obvious economic value. The exploitation methods of the solar energy are mainly divided into photothermic conversion, photoelectric conversion, and photothermic and photoelectric conversion. In order to take full advantage of solar energy, people have attached more and more importance to the exploitation method of photothermic and photoelectric conversion.

With related patents in China, there are only a plurality of inventions related to the utilization methods of the photothermic and photoelectric conversion, and they are as the following. Patent Application No. 200810044255.2 relates to a crystal silicon solar cell component photothermic and photoelectric utilization system, and Patent Application No. 200710063481.0 relates to a solar energy photothermic and photoelectric integration aggregation machine. In the photoelectric and photothermic utilization techniques of the abovementioned patents, all the heat energy is obtained through the method that solar cells are cooled with cooling liquid; meanwhile, the trailing aggregation techniques are not adopted. The abovementioned technical proposals have the following disadvantages: \textcircled{1} as the trailing aggregation techniques are not adopted, the use ratio of solar energy is not high; \textcircled{2} relatively more energy cannot be obtained through the method that solar cells are cooled with cooling liquid; furthermore, it has heat energy with low temperature being less than 100° C.; \textcircled{3} The adopted cell component is unconventional component needed to be redesigned and reassembled; therefore, it has complicated techniques and too difficult for the realization.

Ninety nine point nine percent (99.9%) of solar electromagnet radiation energy is concentrated in the infrared region, the visible region and the ultraviolet region. The wavelength scope of solar radiation which can convert the optical energy to electric energy through photovoltaic cells is about 0.2˜1.25 μm, that is, the light is in a part of the ultraviolet, visible light and near infrared regions. The invention adopts trailing concentrating technique to improve the use ratio. Meanwhile, sunlight selective transmission technique is adopted; therefore, the visible light transmits; most of infrared light reflects, and the energy of each wave band in solar spectrum can be fully utilized.

### SUMMARY OF INVENTION

The invention aims at providing a large trailing-type Fresnel lens point-focusing solar power system. It is a photothermic and photoelectric conversion system which can precisely trail the sun, utilize the sunlight according to wave bands, concentrate heat by high power, and concentrate light by medium and low powers.

The purpose of the invention can be realized by the following technical proposals: it comprises a box body, a point-focusing glass matrix Fresnel lens, a reflecting low-radiation glass, a photovoltaic component, a high-temperature heat accumulator and a tracker, wherein the point-focusing glass Fresnel lens, the reflecting low-radiation glass and the photovoltaic component are arranged in proper sequence from up to down, and respectively arranged on the upper part, the middle part and the low part of the box body. It is preferable that the reflecting low-radiation glass is positioned within the scope of ⅖˜⅗ of the focal length of the point-focusing glass matrix Fresnel lens. The high-temperature heat accumulator is positioned on the point-focusing glass matrix Fresnel lens. The high-temperature heat accumulator is fixed and arranged on a transverse bracket connected with the box body, and the whole box body is arranged on the tracker.

The box body is driven by the tracker, so that the sunlight can always vertically irradiate on the point-focusing glass matrix Fresnel lens. After the sunlight transmits through the point-focusing glass matrix Fresnel lens, it focuses and irradiates on the reflecting low-radiation glass. With the features of sunlight selective-transmission of the reflecting low-radiation glass, for the sunlight irradiating on the reflecting low-radiation glass, most of the infrared reflects and irradiates on the high-temperature heat accumulator, and the rest of the sunlight transmits and irradiates on the photovoltaic component. It might be as well that it focuses again through second lens and irradiates on the photovoltaic component.

### DESCRIPTIONS OF DRAWINGS

The invention is further described with the following drawings;

FIG. 1 is a diagram showing the structure of an embodiment of the invention.

FIG. 2 is a diagram showing the principle underlying an embodiment of the invention.

In the figures, 1. box body; 2. point-focusing glass matrix Fresnel lens; 3. elevation-angle adjustment mechanism; 4. supporting frame; 5. standing column; 6. azimuth-angle adjustment mechanism; 7. transverse bracket; 8. high-temperature heat accumulator; 9. reflecting low-radiation glass; 10. photovoltaic component.

### DETAILED DESCRIPTION OF THE EMBODIMENT

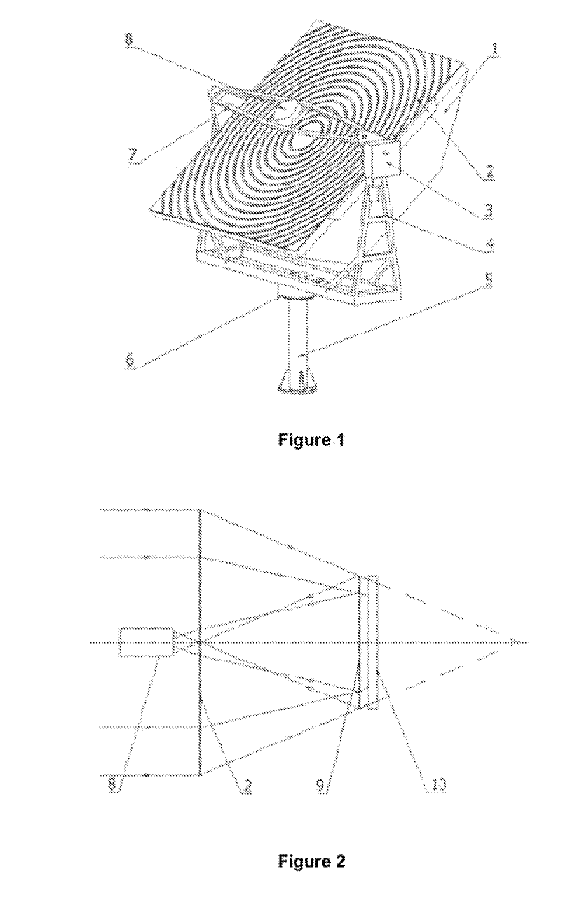

Referring to FIGS. 1 and 2, the embodiment of the invention comprises a box body 1, a point-focusing glass matrix Fresnel lens 2, a reflecting low-radiation glass 9, photovoltaic component 10, a high-temperature heat accumulator 8 and a tracker. The point-focusing glass matrix Fresnel lens 2, the reflecting low-radiation glass 9 and the photovoltaic component 10 are arranged in proper sequence from up to down and respectively arranged on the upper part, middle part and lower part of the box body 1. The reflecting low-radiation glass 9 is positioned in 1/2 of the focal length of the point-focusing glass matrix Fresnel lens 2, and the photovoltaic component 10 is tightly attached to the reflecting low-radiation glass 9. The high-temperature heat accumulator 8 is positioned on the point-focusing glass matrix Fresnel lens 2. The high-temperature heat accumulator 8 is fixed and arranged on the transverse bracket 7 connected with the box body 1. The box body 1 is arranged on the tracker. The box body 1 is driven by the tracker, so that the sunlight can be guaranteed to always vertically irradiate on the point-focusing glass matrix Fresnel lens 2. The sunlight transmits the point-focusing glass matrix Fresnel lens 2 and focuses and irradiates on the reflecting low-radiation glass 9. For the sunlight irradiating on the reflecting low-radiation glass 9, most of infrared reflects and irradiates on the high-temperature heat accumulator 8, and the rest of the sunlight transmits and irradiates on the photovoltaic component 10.

The above-mentioned tracker comprises a standing column 5, an azimuth-angle adjustment mechanism 6, an elevation-angle adjustment mechanism 3 and a supporting frame 4. The azimuth-angle adjustment mechanism 6 is arranged on the upper end of the stand column 5. The supporting frame 4 is arranged on the azimuth-angle adjustment mechanism 6.

The rotation shaft of the above-mentioned box body 1 is arranged on the supporting frame 4, and connected with the elevation-angle adjustment mechanism 3.

The above-mentioned reflecting low-radiation glass 9 is made of ultra-white and float plate glass materials which have high-reflectivity light in solar spectrum with the wavelength being more than and equal to 1.25 μm and have high-transmittance visible light.

The heat-absorbing surface of the above-mentioned high-temperature heat accumulator 8 is made of ceramic material with heat resisting performance and high thermal conductivity. Its main body is made of heat conduction and thermal storage materials with high-temperature and good stable performances.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A trailing-type Fresnel lens point-focusing solar energy system, comprising:
a box body comprising a upper part, a middle part, and a lower part;
a point-focusing glass matrix Fresnel lens;
a reflecting low-radiation glass;
a photovoltaic component;
a high-temperature heat accumulator; and
a tracker, wherein the point-focusing glass matrix Fresnel lens, the reflecting low-radiation glass, and the photovoltaic component are respectively arranged on the upper part, the middle part, and the lower part of the box body, wherein the high-temperature heat accumulator is positioned on the point-focusing glass matrix Fresnel lens, wherein the high-temperature heat accumulator is affixed to a transverse bracket connected with the box body, and the box body is arranged on the tracker.

2. The trailing-type Fresnel lens point-focusing solar energy system according to claim 1, wherein the tracker comprises a standing column, an azimuth-angle adjustment mechanism, an elevation-angle adjustment mechanism, and a supporting frame, wherein the azimuth-angle adjustment mechanism is arranged on the upper end of the standing column, wherein the supporting frame is arranged on the azimuth-angle adjustment mechanism.

3. The trailing-type Fresnel lens point-focusing solar energy system according to claim 2, wherein a rotation shaft of the box body is arranged on the supporting frame and connected with the elevation-angle adjustment mechanism.

4. The trailing-type Fresnel lens point-focusing solar energy system according to claim 1, wherein the reflecting low-radiation glass is made of ultra-white and float plate glass materials that have a high reflectivity to infrared light and a high transmittance to visible light.

5. The trailing-type Fresnel lens point-focusing solar energy system according to claim 1, wherein the heat-absorbing surface of the high-temperature heat accumulator is made of a ceramic material that is heat resistant and has a high thermal conductivity; and its main body is made of heat conduction and thermal storage materials.
